(19) United States
(12) Patent Application Publication
(10) Pub. No.: US 2025/0259413 A1
(43) Pub. Date: Aug. 14, 2025

(54) METHOD AND APPARATUS FOR SEGMENTATION OF SEMICONDUCTOR INSPECTION IMAGES

(71) Applicant: Carl Zeiss SMT GmbH, Oberkochen (DE)

(72) Inventor: Dmitry KLOCHKOV, Schwaebisch Gmuend (DE)

(21) Appl. No.: 19/183,379

(22) Filed: Apr. 18, 2025

Related U.S. Application Data
(63) Continuation of application No. PCT/EP2023/079393, filed on Oct. 23, 2023.

(30) Foreign Application Priority Data
Oct. 26, 2022 (DE) 10 2022 211 348.9

(51) Int. Cl. G06V 10/44; G06T 3/40; G06T 7/00; G06T 7/12; G06T 7/60; G06V 10/26

(52) U.S. Cl. CPC G06V 10/44; G06T 3/40; G06T 7/0004; G06T 7/12; G06T 7/60; G06V 10/26; G06T 2200/24; G06T 2207/20081; G06T 2207/30148

(57) ABSTRACT

A method for segmentation of images using anchor features utilizes prior knowledge and can also be applied to semiconductor features with poor image contrast. The method can be more flexible and robust and involve less user interaction than conventional segmentation methods. With a system incorporating a method of the disclosure, an inspection task of semiconductor objects of interest can be improved and training data for training a machine learning method can be provided.

### CROSS-REFERENCE TO RELATED APPLICATIONS

The present application is a continuation of, and claims benefit under 35 USC 120 to, international application No. PCT/EP2023/079393, filed Oct. 23, 2023, which claims benefit under 35 USC 119 of German Application No. 10 2022 211 348.9, filed Oct. 26, 2022. The entire disclosure of each of these applications is incorporated by reference herein.

### FIELD

The present disclosure relates to a pattern measurement method of semiconductor objects within a semiconductor wafer, as well as a method, computer program product and a corresponding semiconductor inspection device for performing a segmentation of inspection images of semiconductor objects of interest. With the semiconductor inspection device and the method of the disclosure, an inspection task of semiconductor objects of interest can be improved or training data for training a machine learning method for wafer inspection can be provided. The method, computer program product and semiconductor inspection device can be utilized for different inspection tasks, such as quantitative metrology, defect detection, process monitoring, or defect review of integrated circuits within semiconductor wafers.

### BACKGROUND

Semiconductor structures are amongst the finest man-made structures. Semiconductor manufacturing involves precise manipulation, e.g., lithography or etching, of materials such as silicon or oxide at very fine scales in the range of nm. A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patters are subject to several influences. For example, during the manufacturing of 3D-memory devices, the processes currently include etching and deposition. Other process steps such as the lithography exposure or implantation also can have an impact on the properties of the elements of the integrated circuits. Fabricated semiconductor structures can suffer from rare and different imperfections. Devices for quantitative metrology, defect-detection or defect review look for these imperfections. These devices are not only used during wafer fabrication. As this fabrication process can be complicated and highly non-linear, optimization of production process parameters can be difficult. As a remedy, an iteration scheme called process window qualification (PWQ) can be applied. In each iteration a test wafer is manufactured based on the currently best process parameters, with different dies of the wafer being exposed to different manufacturing conditions. By detecting and analyzing the test structures with devices for quantitative metrology and defect-detection, the best manufacturing process parameters can be selected. In this way, production process parameters can be tweaked towards optimality. Afterwards, a highly accurate quality control process and device for the metrology semiconductor structures in wafers is used.

Fabricated semiconductor structures are usually based on prior knowledge. The semiconductor structures are manufactured from a sequence of layers being parallel to a substrate. For example, in a logic type sample, metal lines are running parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average. Furthermore, a semiconductor wafer typically has a diameter of 300 millimeter (mm) and consist of a plurality of several sites, so called dies, each comprising at least one integrated circuit pattern such as for example for a memory chip or for a processor chip. During fabrication, semiconductor wafers run through about 1000 process steps, and within the semiconductor wafer, about 100 or more parallel layers are formed, comprising the transistor layers, the layers of the middle of the line, and the interconnect layers and, in memory devices, a plurality of 3D arrays of memory cells.

The aspect ratio and the number of layers of integrated circuits, in general, constantly increase and the structures are growing into the third (vertical) dimension. The current height of the memory stacks exceeds a dozen of microns. In contrast, the features size is generally becoming smaller. The minimum feature size or critical dimension is below 10 nanometers (nm), for example 7 nm or 5 nm, and is expected to approach feature sizes below 3 nm in near future. While the complexity and dimensions of the semiconductor structures are growing into the third dimension, the lateral dimensions of integrated semiconductor structures are becoming smaller. Therefore, measuring the shape, dimensions and orientation of the features and patterns in 3D and their overlay with high precision can be challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter has a limited dimension, which depends on the charged particle beam operation conditions and lens. The beam resolution is limited by approximately half of the beam diameter. The lateral resolution can be below 2 nm, for example even below 1 nm.

A common way to generate 3D tomographic data from semiconductor samples on nanometer scale is the so-called slice and image approach obtained for example by a dual beam device. A slice-and image approach is described in WO 2020/244795 A1. According to the method of the WO 2020/244795 A1, a 3D volume inspection is obtained at an inspection sample extracted from a semiconductor wafer. In another example, the slice and image method is applied under a slanted angle into the surface of a semiconductor wafer, as described in WO 2021/180600 A1. According to this method, a 3D volume image of an inspection volume is obtained by slicing and imaging a plurality of cross-section surfaces within the inspection volume. For a precise measurement, a large number N of cross-section surfaces in the inspection volume is generated, with the number N exceeding 100 or even more image slices. For example, in a volume with a lateral dimension of 5 μm and a slicing distance of 5 nm, 1000 slices are milled and imaged. With a typical sample of a plurality of high aspect ratio (HAR) structures with a pitch of for example 70 nm, about 5000 HAR structures are in one field of view, and a total sum of more than five million cross sections of HAR structures is generated. Several improvements have been proposed to reduce the huge computational effort of extracting the desired measurement results. WO 2021/180600 A1 illustrates some methods which utilizes a reduced number of images slices. In an example, the method applies a-priori information.

A goal of semiconductor inspection is to determine a set of specific parameters of semiconductor objects such as HAR structures inside the inspection volume. Such parameters are for example a dimension, area, a shape, or other measurement parameters. Typically, known measurement tasks involve several computational steps like object detection, feature extraction, and any kind of a metrology operation, for example a computation of a distance, a radius or an area from the extracted features. Of these many steps, each generally involves a relatively high computational effort.

Generally, semiconductors comprise many repetitive three-dimensional structures. During the manufacturing process or a process development, some selected physical or geometrical parameters of a representative plurality of the three-dimensional structures are measured with relatively high accuracy and high throughput. For monitoring the manufacturing, an inspection volume is defined, comprising the representative plurality the three-dimensional structures. This inspection volume is then analyzed for example by a slice and image approach, leading to a 3D volume image of the inspection volume with high resolution.

The plurality of repetitive three-dimensional structures inside an inspection volume can exceed several hundreds or even several thousands of individual structures. Thereby, a huge number of cross section images is generated, for example at least 100 three-dimensional semiconductor objects of interest are investigated for example by 100 cross section image slices. Thus, the number of cross section image segments of the semiconductor objects of interest to be detected may easily reach 10,000 or more. In order to try to minimize a measurement time, an image acquisition time with a charged particle beam device might be reduced as much as possible at the expense of a higher noise level, making the object detection even more difficult and prone to errors.

Machine learning is a field of artificial intelligence. Machine learning algorithms generally build a machine learning model based on training data consisting of a large number of training samples. After training, the algorithm is able to generalize the knowledge gained from the training data to new previously unencountered samples, thereby making predictions for new data. There are many machine learning algorithms, e.g., linear regression k-means or neural networks. For example, Deep learning is a class of machine learning that uses artificial neural networks with numerous hidden layers between the input layer and the output layer. Due to this extensive internal structure the networks are able to progressively extract higher-level features from the raw input data.

Each level learns to transform its input data into a slightly more abstract and composite representation, thus deriving low and high level knowledge from the training data. The hidden layers can have differing sizes and tasks such as convolutional or pooling layers. Machine learning is frequently applied to object detection or object classification during semiconductor inspection. For example, a machine learning algorithm is trained to detect features of semiconductor object of interest in a cross-section image segment. The training data typically involve many images of identified and segmented cross section images with for example a pixel-by-pixel annotation.

Typical machine learning algorithms involve an intensive generation of training data, including intensive interaction by an operator or user. The user usually annotates a huge set of images with annotation tags for successfully training a machine learning algorithm. This is hardly feasible due to the large annotation effort. A recent example for generating training data for inspection tasks at semiconductor objects of interest is shown in U.S. application Ser. No. 17/701,054, filed on Mar. 3, 2022 (published as US 2023/0196189), which is hereby incorporated herein by reference. The method according to U.S. application Ser. No. 17/701,054 utilizes a parametrized description of the semiconductor objects of interest and methods to adjust the parametrized description to measured cross section images of semiconductor objects of interest.

### SUMMARY

The disclosure seeks to provide an efficient method to perform segmentation and annotation of large datasets of cross section images of semiconductor objects of interest. The disclosure seeks to provide a method of segmentation and annotation which is more robust against imaging noise or low image contrasts. The disclosure seeks to improve certain known methods for segmenting and annotating HAR channels. The disclosure seeks to reduce the amount of user interaction during a segmentation and annotation. Generally, the disclosure seeks to provide a wafer inspection system for the inspection of semiconductor structures in inspection volumes with high throughput and high accuracy. The disclosure seeks to provide a wafer inspection method for the measurement of semiconductor structures in inspection volumes, which can quickly be adapted to changes of the measurement tasks, the measurement system, or to changes of the semiconductor object of interest.

The disclosure can provide an improved method to perform segmentation and annotation of large datasets of cross section images of semiconductor objects of interest. The disclosure can provide an inspection system configured to perform the improved method of segmentation and annotation. An improved method of segmentation and annotation is more robust against imaging noise or low image contrasts. In an example, a method for segmenting and annotating HAR channels is provided. With an improved method of segmentation and annotation, an amount of user interaction can be reduced. The disclosure can provide a wafer inspection system for the inspection of semiconductor structures in inspection volumes with high throughput and high accuracy and a wafer inspection method for the inspection of semiconductor structures in inspection volumes, which can quickly be adapted to changes of the inspection tasks, the inspection system, or to changes of the semiconductor object of interest.

According to an embodiment, a method of contour extraction of a semiconductor object of interest comprises a step of selecting a first feature of the semiconductor object of interest as an anchor feature. The method further comprises a step of defining a transfer property from a first contour of the anchor feature to a second contour of a second feature of the semiconductor object of interest. The method further comprises a step of obtaining at least one cross-section image or image segment, comprising at least one cross-section of the semiconductor object of interest. The method further comprises a step of generating a first contour of the anchor feature in the cross-section image and a step of determining a second contour from the first contour with the transfer property. Thereby, a second contour can be determined with improved accuracy, even is an image noise is very large or a second feature is imaged with low imaging contrast. By selecting the anchor feature to provide for example large image contrast during imaging, or by selecting the anchor feature as a feature of the semiconductor of interest, which can be unambiguously detected, a detection of a first feature of the semiconductor object of interest is warranted. With the predefined transfer property derived for example from CAD data, a transfer of the first contour to a second or further contour of the semiconductor object of interest is enabled. By selecting the anchor feature as a feature of the semiconductor object of interest with high image contrast and large edge slopes, a stable determination of a first contour of the first or anchor feature is enabled and a transfer to a second contour of second or further feature is possible.

In an example, the generation of the first contour comprises generating an initial contour proposal from a cross-section image by image processing comprising at least one member of the group consisting of an intensity calibration, threshold operation, a computation of an intensity gradient, or a computation of the normalized image log slope (NILS). In an example, the generation of the first contour comprises modifying the initial contour proposal by image processing comprising at least one member of the group consisting of a smoothing, an interpolation, a contour closing, a contour vector extraction, or an active contour model. An image processing can be based on prior knowledge of the contour shape of the anchor feature.

In an example, the transfer property for determining the second contour comprises at least one member of a group consisting of a scaling, an anisotropic scaling, a morphing operation, a shift, a rotation, a shearing, or a template scaling. The step of determining the second contour can further comprise an image processing comprising at least one member of the group consisting of a smoothing, an interpolation, a contour closing, a contour vector extraction, or an active contour model. A template scaling can rely on prior knowledge of the shape of a semiconductor object of interest, wherein a second contour is predefined as a template with a predefined scaling property to for example a diameter or an area of a first contour of an anchor feature.

In an example, the method further comprises a detection of at least on instance of a semiconductor object of interest within a cross-section image by a method comprising a member of the group consisting of a template matching, a thresholding, or a correlation technique. The method can further comprise at least one member of a group consisting of a registration, a distortion correction, a magnification adjustment, a computation of a depth map, a contrast enhancement, and a noise filtering of a cross-section image.

In an example, the method of contour extraction is iteratively repeated, including the repeated obtaining of cross-section images, generating a plurality of first contours, and determining a plurality of second contours with the transfer property from the plurality of first contours. The at least one cross-section image with determined contours can be annotated with pixel values according to the plurality of first and second contours and used for the training of an object detector. Thereby, a large number of training data can be generated with reduced user interaction and with increased speed of an acquisition of cross-section images with increased noise level.

In an example, the method of contour extraction comprises determining a property of a second feature. The property can be at least a member of the group consisting of a diameter, an area, a center of gravity, a deviation of a shape, an eccentricity, a distance. Thereby, a measurement task or a defect detection can be achieved with less user interaction and with increased speed of an acquisition of cross-section images with increased noise level.

In a second embodiment, a wafer inspection system is given. The wafer inspection system comprises a dual beam system and an operation control unit, comprising at least one processing engine and a memory. The processing engine is configured to execute software instructions stored in the memory, comprising instructions according to a method of the first embodiment. In an example, the wafer inspection system further comprising an interface unit and a user interface configured to receive, display, send, or store information, information including the transfer property and the selection of an anchor feature of a semiconductor object of interest.

A wafer inspection system for performing an inspection task of semiconductor objects comprises the following features: an imaging device adapted to provide at least one cross-section image of a wafer; a graphical user interface configured to present data to the user and obtain input data from the user, one or more processing devices; and one or more machine-readable hardware storage devices comprising instructions that are executable by one or more processing devices to perform operations comprising one of the methods disclosed herein. The disclosure also relates to one or more machine-readable hardware storage devices comprising instructions that are executable by one or more processing devices to perform operations according to the first embodiment.

In an example, the dual beam system comprises a focused ion beam (FIB) system and a charged particle beam imaging system arranged at an angle such that during use, a focused ion beam and a charged particle beam form an intersection point. The dual beam system is configured such that during use at least a cross section image is formed through an inspection volume of a wafer at a slanted angle GF with respect to a wafer surface. The dual beam system can be configured for a slice-and image generation process at a wafer in a wedge-cut geometry with the slanted angle GF below 45°, for example 30° or even less.

With a system and method according to the first or second embodiments, for example, a wafer inspection of semiconductor objects inside of the inspection volume can be provided with high throughput, high accuracy, and reduced damage to the wafer. It is further possible to quickly adapt a wafer inspection task of semiconductor objects of interest to changing conditions, for example changes of the measurement tasks, changes of the charged particle beam imaging system, or to changes of the semiconductor object of interest itself. Therefore, a generalized wafer inspection method with high flexibility can be provided. The method and system can be used for defect detection, process monitoring, defect review, quantitative metrology, and inspection of integrated circuits within semiconductor wafers.

While the examples and embodiments are described with reference to semiconductor wafers, it is understood that the disclosure is not limited to semiconductor wafers but can for example also be applied to reticles or masks for semiconductor fabrication.

The disclosure described by examples and embodiments is not limited to the embodiments and examples but can be implemented by those skilled in the art by various combinations or modifications thereof.

### BRIEF DESCRIPTION OF THE DRAWINGS

The present disclosure will be even more fully understood with reference to the following drawings.

FIG. 1 shows an illustration of a wafer inspection or metrology system for 3D volume inspection with a dual beam device.

FIG. 2 is an illustration of the slice-and image method of a volume inspection in a wafer.

FIG. 3 illustrates an example of a cross section image, obtained by a slice-and image method.

FIG. 4 is an illustration of a flow chart of a method according to an embodiment.

FIGS. 5A-5C illustrate a cross-section through a semiconductor object of interest.

FIGS. 6A-6E illustrate results of some method steps according to an embodiment.

FIGS. 7A-7D illustrate results of FIGS. 6A-6D without noise.

FIGS. 8A-8B illustrate an example of a method according to an embodiment.

FIGS. 9A-9D illustrate an example of a method according to an embodiment.

FIG. 10 illustrates a flow chart of an inspection method.

FIGS. 11A-11B illustrate a result of an inspection.

FIG. 12 shows an inspection system according to an embodiment.

### DETAILED DESCRIPTION

Throughout the figures and the description, same reference numbers are used to describe same features or components. The coordinate system is selected that the wafer surface 55 coincides with the XY-plane.

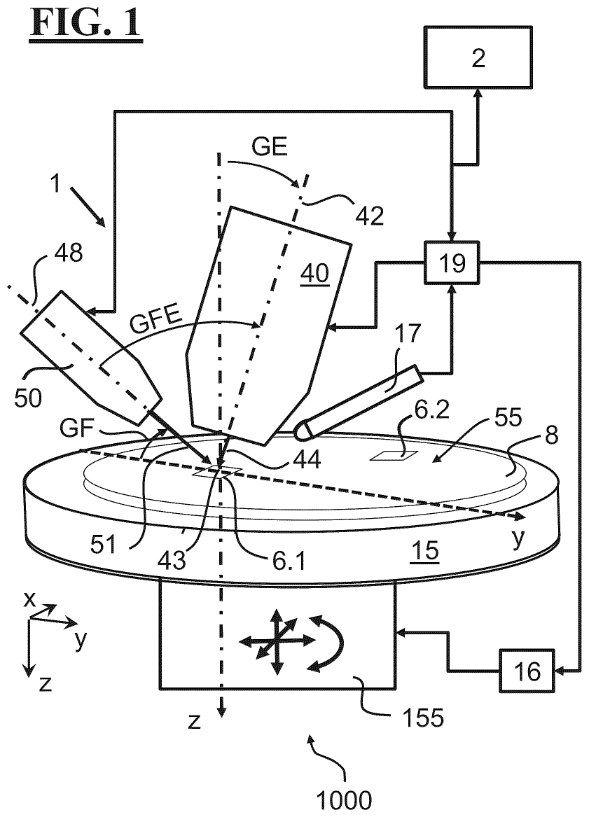

Recently, for the investigation of 3D inspection volumes in semiconductor wafers, a slice and imaging method has been proposed, which is applicable to inspection volumes inside a wafer. Thereby, a 3D volume image is generated at an inspection volume inside a wafer in the so called “wedge-cut” approach or wedge-cut geometry, without the need of a removal of a sample from the wafer. The slice and image method is applied to an inspection volume with dimensions of few um, for example with a lateral extension of 5 micrometers (μm) to 10 μm in wafers with diameters of 200 mm or 300 mm. The lateral extension can also be larger and reach up to few 10ths of micrometers. A V-shaped groove or edge is milled in the top surface of an integrated semiconductor wafer to make accessible a cross-section surface at an angle to the top surface. 3D volume images of inspection volumes are acquired at a limited number of inspection sites, for example representative sites of dies, for example at process control monitors (PCM), or at sites identified by other inspection tools. The slice and image method usually will destroy the wafer only locally, and other dies may still be used, or the wafer may still be used for further processing. The methods and inspection systems according to the 3D Volume image generation are described in WO 2021/180600 A1, which is fully incorporated herein by reference. An example of a wafer inspection system 1000 for 3D volume inspection is illustrated in FIG. 1. The wafer inspection system 1000 is configured for a slice and imaging method under a wedge cut geometry with a dual beam device 1. For a wafer 8, several inspection sites, comprising inspection sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as Laser interferometers are known in the art. A control unit 16 is configured to control the wafer stage 155 and to adjust an inspection site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE, and the CPB imaging system axis forms an angle GE with the normal to the wafer surface 55. In the coordinate system of FIG. 1, the normal to the wafer surface 55 is given by the z-axis. The focused ion beam 51 is generated by the FIB-column 50 and impinges under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at inspection site 6.1, and secondary particles as well as scattered particles are generated. Particle detector 17 collects at least some of the secondary particles and scattered particles and communicates the particle count with a control unit 19. Other detectors for other of interaction products may be present as well. Control unit 19 is in control of the charged particle beam imaging column 40, of FIB column 50 and connected to a control unit 16 to control the position of the wafer 8 mounted on the wafer support table 15 via the wafer stage 155. Control unit 19 communicates with operation control unit 2, which triggers placement and alignment for example of inspection site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM). In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface 55.

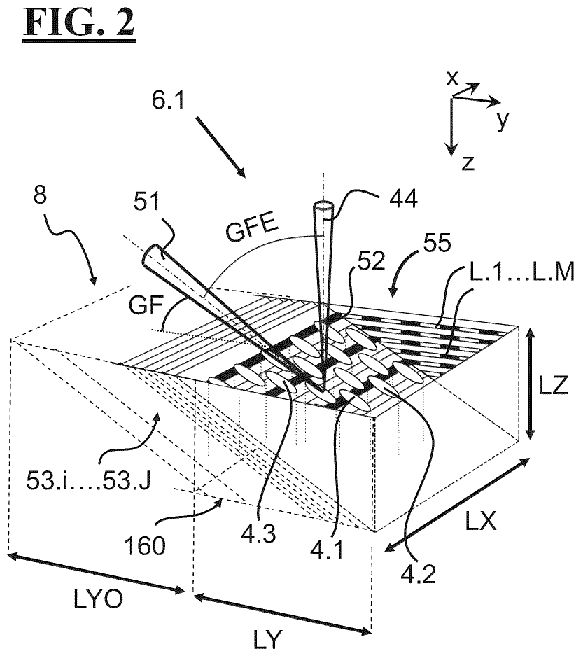

FIG. 2 illustrates the wedge cut geometry at the example of a 3D-memory stack. FIG. 2 illustrates the situation, when the surface 52 is the new cross-section surface which was milled last by FIB 51. The cross-section surface 52 is scanned for example by SEM beam 44, which is in the example of FIG. 2 arranged at normal incidence to the wafer surface 55, and a high-resolution cross-section image slice is generated. The cross-section surfaces 53.1 . . . 53.N are subsequently milled with a FIB beam 51 at an angle GF of approximately 30° to the wafer surface 9, but other angles GF, for example between GF=20° and GF=60° are possible as well. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN— or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44. During repeated milling an imaging, a plurality of cross sections is formed and a plurality of cross section images are obtained, such that an inspection volume of size LX×LY×LZ is properly sampled and for example a 3D volume image can be generated. Thereby, the damage to the wafer is limited to the inspection volume plus a damaged volume in y-direction of length LYO. With an inspection depth LZ about 10 μm, the additional damage volume in y-direction is typically limited to below 20 μm.

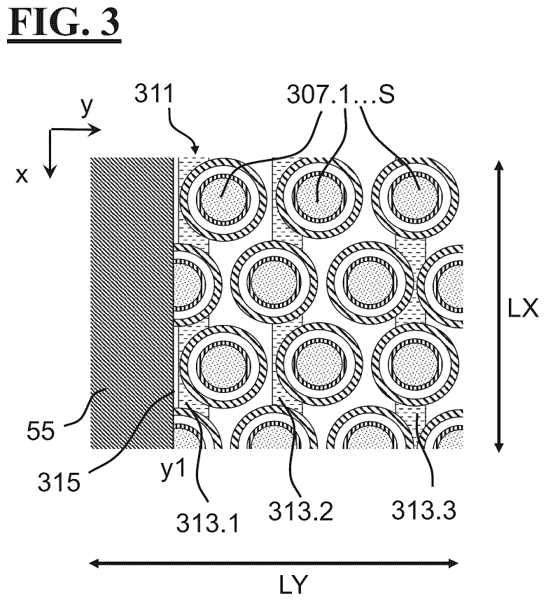

FIG. 3 shows an example of a cross-section image slice 311 generated by the imaging charged particle beam 44, corresponding to the cross-section surface 52. The cross-section image slice 311 comprises an edge line 315 between the slanted cross-section and the surface 55 of the wafer at the edge coordinate y1. Right to the edge, the image slice 311 shows several cross-sections 307.1 . . . 307.S through the HAR structures which are intersected by the cross-section surface 52. In addition, the image slice 311 comprises cross-sections of several word lines 313.1 to 313.3 at different depths or z-positions. With these word lines 313.1 to 313.3, a depth map Z₁(x,y) of the slanted cross-section surface 52 can be generated.

According to a first embodiment, a relatively fast and robust method for performing a segmentation and annotation of a cross-section image of a semiconductor object of interest can be provided. The semiconductor object of interest is for example a HAR structure of a NAND device with cross sections 307.1 . . . 307.S as shown in FIG. 3. Segmentation and annotation is for example used for the generation of annotated training image data for training a machine learning method to detect and attribute new instances of cross sections of the semiconductor object of interest in for example routine inspection tasks.

A typical method for performing an inspection task utilizes a two-step approach. Such a two-step approach is disclosed in international patent application PCT/EP2022/057656with priority from Apr. 21, 2021, which is hereby incorporated by reference. In a first step, new instances of cross sections of the semiconductor object of interest are detected by a first machine learning method, which has been trained by annotated training image data. The first machine learning method is sometimes also called the object detector. In a second step, the detected instances of cross sections of the semiconductor object of interest are analyzed for example by image processing, including performing measurements, or a second machine learning method, trained for example to classify defects or deviations. The method according to the first embodiment improves the step of generating the training data of the first machine learning method or object detector. With the improved method of generating training data for an object detector, a method of wafer inspection is generally improved. The proposed method of improved segmentation is however not limited to the case where training data for an object detector has to be generated. The result segmentation method can also be directly applied to a measurement task of a defect inspection task.

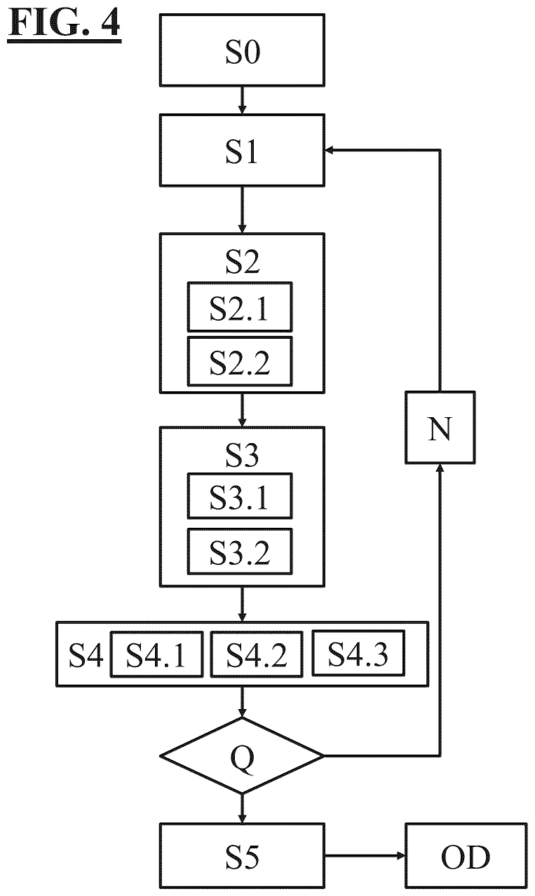

The method according to the first embodiment comprises a two-step solution for generating the contour for a feature of interest. First, a first contour corresponding to a pronounced edge of an anchor feature is extracted using a standard method. Second, a second contour for the feature of interest is generated using the first contour. The method invokes the known transfer property between the first contour of the anchor feature and a second contour proposal. Finally, a refinement of the second contour proposal around the feature of interest is performed. The second contour proposal can be generated based on the location of any detected part of the feature of interest using a priori knowledge about the geometry of for example a repetitive feature. For example, if the location of the feature of interest or of any part of it is determined by an object detection method (for example, by a cross-correlation with a template), the second contour proposal can be generated based solely on the determined centroid of the feature. FIG. 4 shows an example of a flow chart for a method according to the first embodiment. A method of contour extraction of a semiconductor object of interest, comprises the steps of selecting a first feature of the semiconductor object of interest as an anchor feature and defining a transfer property from a first contour of the anchor feature to a second contour of a second feature of the semiconductor object of interest. After obtaining a cross-section image of the semiconductor object of interest, a first contour of the anchor feature in the cross-section image is generated by standard methods. The second contour is derived from the first contour with the transfer property.

In step S0, an object detection task is specified and further processing information corresponding to a semiconductor object of interest is collected. For example, a template of the semiconductor object of interest, for example an HAR structure 307 as shown in FIG. 3, is specified. A semiconductor object of interest comprises multiple features with multiple contours or edges. Those multiple contours or edges define the template of the semiconductor object of interest. The specification can for example comprise an expectation value of the number of concentric rings within an HAR structure 307 and the expected diameter of each ring. Further, a regularity of a plurality of HAR structures 307 is specified, for example a hexagonal raster with an expectation value for the raster grid spacing. Generally, the template of the semiconductor object of interest can comprise several features of the semiconductor object of interest, and relations between the features or between at least one feature and a reference feature. The specification of the object detection task can be obtained from a memory of input device as a predetermined specification of the HAR object detection task. The specification of the object detection task can also be obtained or modified via a user interface.

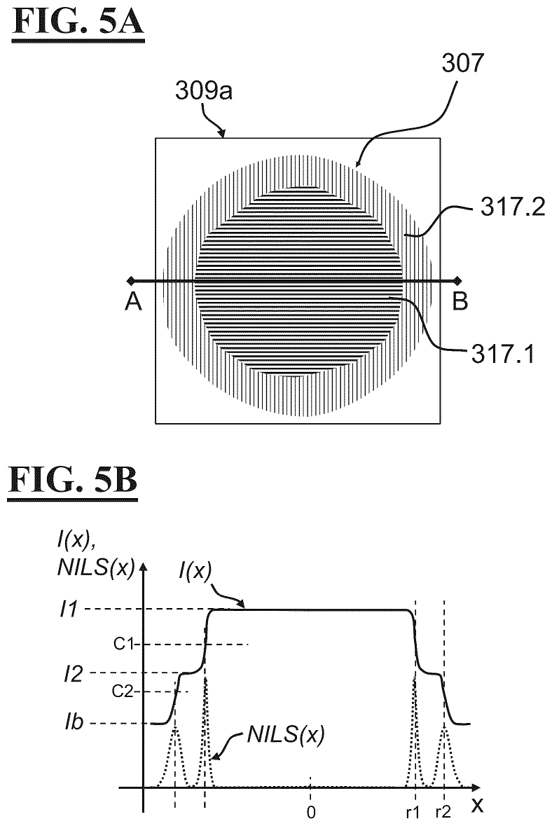

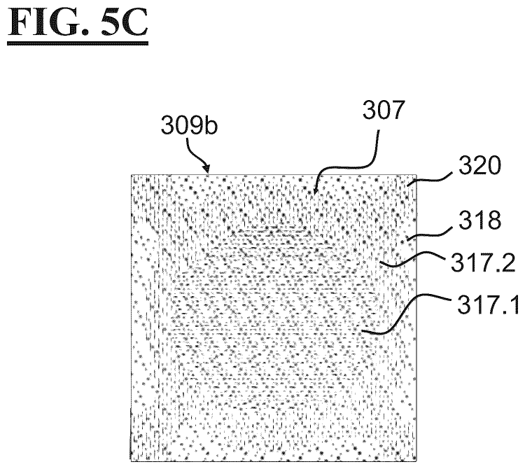

Some of the contours are pronounced and can more easily be detected for example by standard image processing techniques such as thresholding operations or contrast slope operations. During specification of the object detection task, a feature is selected whose contour or edge is more easily detected by image processing techniques. This feature is also called the “anchor feature”. An example of an image segment 309 of a cross-section image slice 311 comprising one cross section through a semiconductor object of interest is shown in FIGS. 5A-5C. FIG. 5A shows an idealized cross-section image through a single HAR structure comprising only two features or ring zones 317.1 and 317.2. FIG. 5A shows an image segment 309a with the ideal contrast of a SEM image, determined by the material contrast corresponding to the materials within ring zones 317.1 and 317.2. FIG. 5B shows the image intensity I(x) along line A-B through the cross-section image segment 309a. The image intensity I(x) is shown in arbitrary units with three intensity levels, the background intensity level Ib, the first intensity level I1 of first ring zone 317.1 and the second intensity level I2 of the second ring zone 317.2. The radii r1 and r2 of the first and second ring zones 317.1 and 317.2 correspond to intensity values c1 and c2. The intensity thresholds C1 and C2 can be determined in advance, for example by prior knowledge of the radii from for example CAD data. The threshold intensity values C1 and C2 can also be selected by a user, for example via a user input. For example, a user may determine the thresholds according to a normalized image slope I′(x) or NILS of a cross section image, such that an intensity threshold C1 corresponds to a maximum NILS value. Typically, the NILS(x) shows a maximum value at the transition of ring zones, for example from the first ring zone 317.1 to the second ring zone 317.2.

FIG. 5C shows a more realistic image segment 309b with the real contrast of a SEM image. Due to for example a limited image acquisition time, a SEM image is subject to image noise or shot noise, and an additional signal from a background 318, for example generated by underlying layers. An interaction zone of a primary electron beamlet has typically an extension of about 5 nm to 20 nm within a wafer sample, and thus secondary electrons are also collected from deeper, underlying structures. The inner channel edge around the dark core or first ring zone 317.1 is still pronounced and can be detected using for example thresholding. The inner channel edge around the first ring zone 317.1 thus can form the anchor feature of this inspection task. Due to the image noise and the poor contrast of the second, outer ring 317.2, a contour extraction of the outer contour of the second ring 317.2 it is prone to errors or even not possible. An outer contour of the second ring 317.2 may even appear to be partially merged with neighboring HAR structures, such as illustrated by the bridges 320. A contour of the outer edge of the second ring zone 317.2 cannot easily be generated by thresholding. The outer edge of the second ring zone 317.2, however, is typically the main interest of the inspection task of HAR channels.

After selection and definition of the anchor feature, a transfer property of the contours of other features of the semiconductor object of interest is defined. The transfer property can for example be a simply scaling property of a first contour of a first ring zone to a second contour of a second ring zone. The scaling property is for example derived from the different radii r1 and r2 provided by design information, such that a second contour line with radius r2 is derived by scaling a first contour line with radius r1 with scaling factor r2/r1. For example, the first contour line is extracted at the anchor feature, and contour lines of further features are derived by scaling.

In a first step S1, a cross-section image slice 311 of the semiconductor object of interest is obtained. The cross-section image slice 311 is for example generated by a slice-and image process with a dual beam system 1. The cross-section image slice 311 can also be obtained from a data memory of a data processing system. The cross-section image slice 311 can be registered according to predetermined registration features such as fiducials. The cross-section image slice 311 can further be subject to an image processing, including for example an intensity calibration, a distortion correction, a magnification adjustment, a computation of a depth map, a global or local contrast enhancement, a noise filtering. Optionally, the cross-section image slice 311 is displayed with a display of a user interface.

In an example, during step S1, instances of the semiconductor object of interest 307 are detected for example by matched filters or template matching, thresholding, or other correlation techniques known in the art. The detected of instances of the semiconductor object of interest 307 also can follow prior information, for example if repetitive semiconductor object of interest 307 such as HAR structures are investigated, or from a registration of a cross-section image slice 311 with respect to CAD information or alignment fiducials.

In a second step S2, a first contour of the anchor feature is generated. The anchor feature is for example the anchor feature selected in step S0. In Step S2.1, an initial contour proposal is generated by a fast and simple image processing operation. Such an operation can for example be a simple clipping or threshold operation with an image intensity level C1 of a properly intensity-calibrated cross-section image segment 309. Another example is the computation of the intensity gradient I′(x) or the NILS(X) as illustrated above in FIG. 5B.

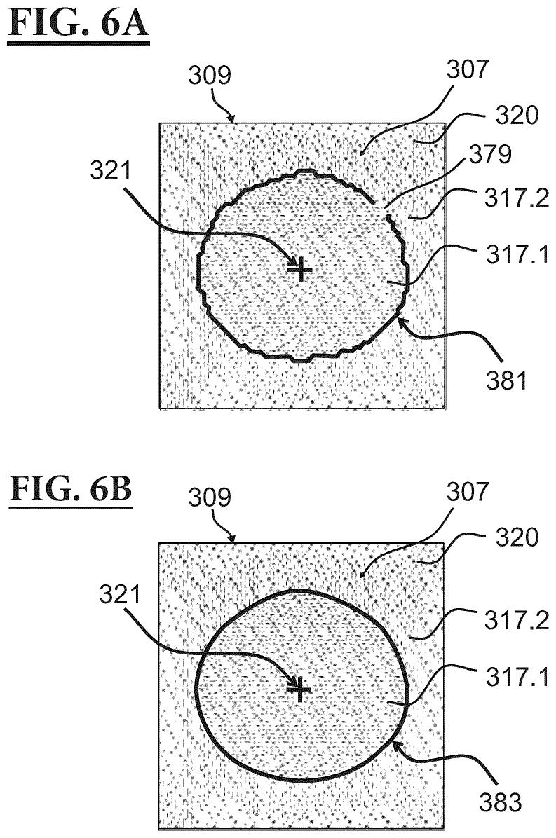

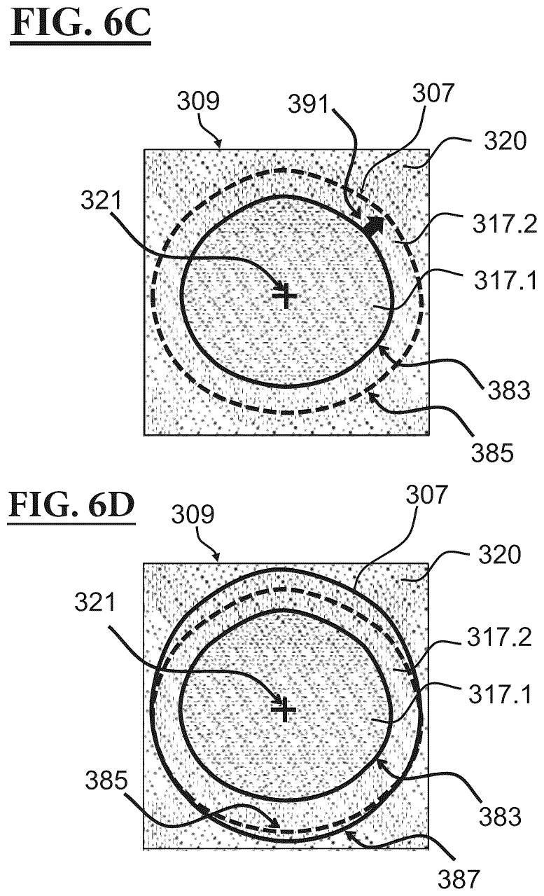

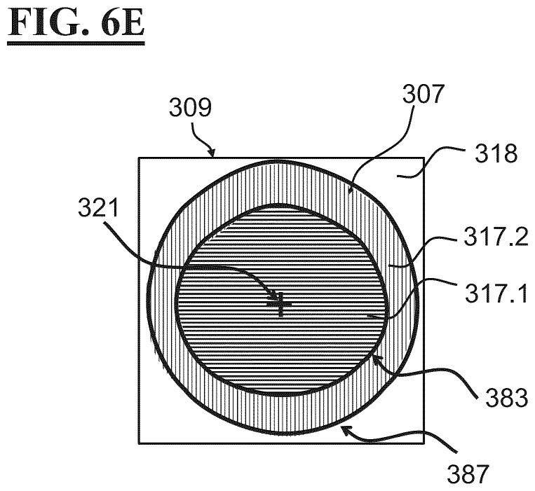

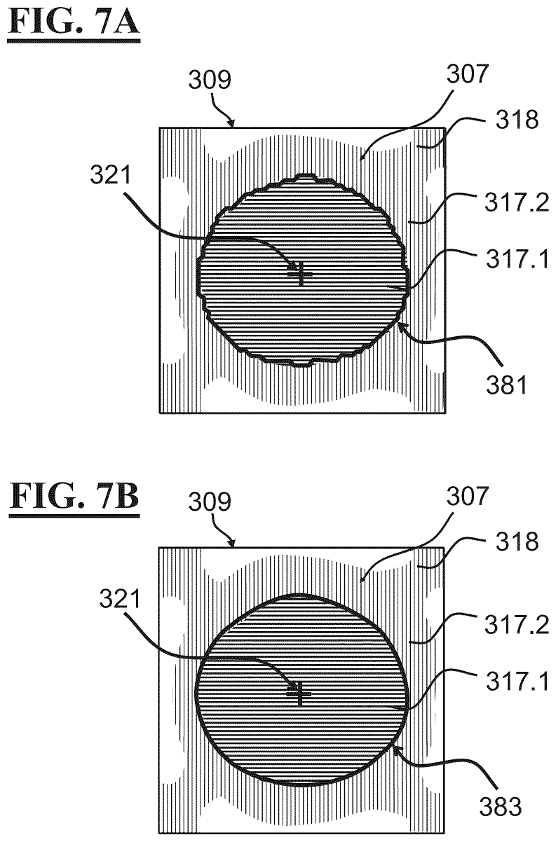

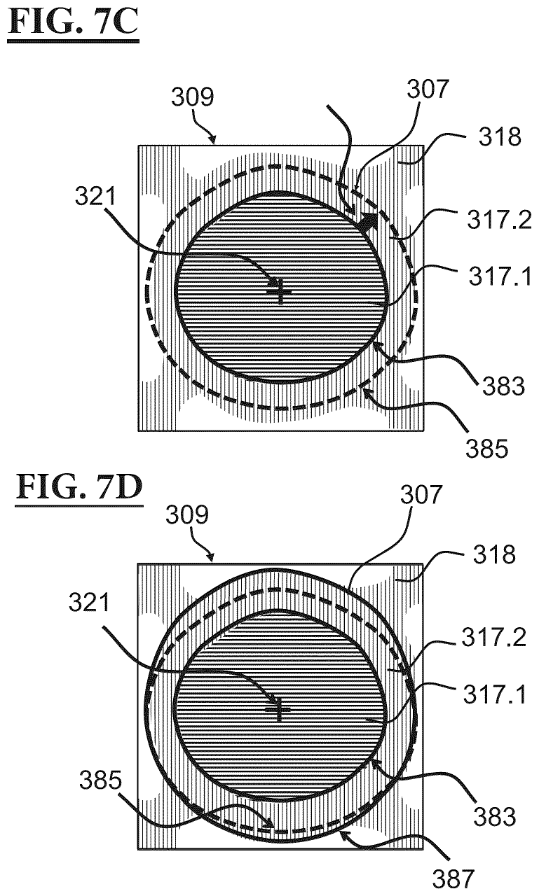

FIGS. 6A-6E illustrate the results of the method steps at the example of a SEM image segment 309 of a semiconductor object of interest, in the example of the HAR channel of FIGS. 5A-5C having two ring zones 317.1 and 317.2. FIGS. 7A-7D illustrate the SEM image segments 309 provided in FIGS. 6A-d without the image noise for better visibility. FIG. 6A illustrates an example of the result of step S2.1. The initial contour proposal 381 is shown at individual image pixels according to the selected criterium for each image pixel. The selected criterium can for example be an intensity threshold or a local maximum value of a NILS-value. The contour proposal 381 includes individually flagged pixels, and there can be missing pixels such as contour gap 379.

In optional Step S2.2, the initial pixelated contour proposal 381 is analyzed and modified, and the contour line 383 of the anchor feature is determined. The analysis and modification can comprise image processing methods such as smoothing operations, interpixel interpolations, contour closing to fill gaps 379. Further steps can include the determination of a contour line vector, representing the contour line 383, and a determination of a geometrical description of the contour line 383, for example by a spline interpolation. An analysis and modification of the initial pixelated contour proposal 381 is given by the so-called “active contour model”, also called “snakes” in the framework of computer vision. According to this approach, a deformable model of a contour line is matched to an image by optimization. The deformable model is for example derived from a spline interpolation to the initial pixelated contour proposal 381. As an optimization target, prior knowledge of the contour shape is applied, which can for example provided from CAD information or via user specification.

In an example, the contour line 383 is used as first contour of the anchor feature. However, also the contour proposal 381 may be directly used as first contour of the anchor feature.

In Step S3, a second contour of a second feature different from the anchor feature is determined. In step 3.1, a second contour proposal of the second feature is determined from the first contour of the anchor feature determined in step S2. The determination follows according to the transfer property defined in step S0. An example is illustrated in FIG. 6c. The transfer property in this example was determined according to a scaling of the first to the second contour with the scaling factor r2/r1 according to design radii r1 and r2 of the ring zones of an HAR channel. The first contour line 381 or 383 is scaled (illustrated by scaling vector 391) to form the second contour proposal 385 of the second feature, here the second ring zone 317.2. Other transformations a possible as well, including as shift, a rotation, a shear operation, a morphing operation, an anisotropic scaling, or including a relative scaling of a contour template of a second feature of different shape compared to the anchor feature. For template scaling, a template of the second feature is defined in step S0 and a transfer property of the template is defined according to a property of the first contour of the anchor feature. The template of the second feature is for example defined according to the design-shape of a semiconductor object of interest and a predefined scaling property to for example a diameter or an area of a first contour of an anchor feature.

In step 3.2, the second contour proposal 385 is analyzed and modified, similar to step S2.1, and the second contour line of the second feature is determined. The analysis and modification can comprise methods as described in connection with step S2.2, for example by application of the active contour model, using prior knowledge of the contour shape of the second feature. A result is illustrated in FIG. 6d, with the second contour line 387 generated from the second contour proposal 383.

Step S4 comprises several alternatives.

In optional step S4.1, the cross-section image segment 309 is automatically annotated pixel by pixel according to areas limited by the first contour 381 or 383 and the second contour 385 or 387. Such annotated images are for example used as training data for an object detector.

In optional step S4.2, a parameter or property of the second feature is determined, for example a diameter, an area, a center of gravity, a deviation from a design shape, an eccentricity, a distance to another semiconductor object of interest, e.g. a distance to a second feature of a second HAR channel. The kind of determination can be selected by a user input and performed by operations known in the art. The parameter or property of such a determination can be used as an annotation label for the cross-section image segment for us as training data for training a machine learning algorithm for wafer inspection.

In optional step S4.3, the results of step S4.1 or step 4.2 or both are stored in a memory for later use.

The method is iteratively continued with step N, in which the next cross-section image slice of a semiconductor object of interest is obtained and provided as input to Step S1. In an example, each cross-section image slice comprises several instances of a semiconductor object of interest and the method steps S1 to S4 is repeated for each detected instance of a semiconductor object of interest within each cross-section image slice.

The iteration continues until a break criterion is determined in Step Q. A break criterion is for example reached when a sufficient number or training data for training of an object detector has been generated. In optional Step S5, the training data are then used for training of an object detector OD. The trained object detector can the be used for object detection during a wafer inspection task.

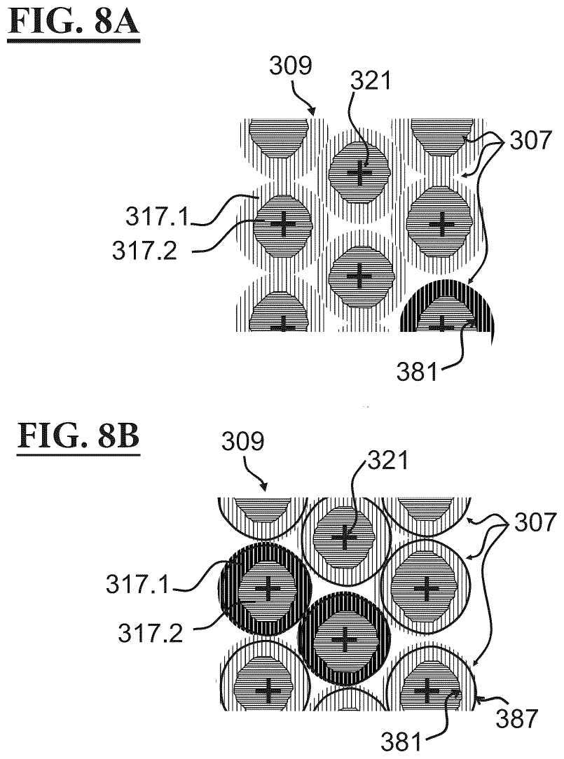

FIGS. 8A-8B illustrate another example of the method. Here, the initial contour proposals 381 are directly applied (FIG. 8A) for generating the contours of the second feature 387 (FIG. 8B) according to step S3 and step S2.2 is skipped. In another example, the center points 321 of the HAR structures 307 are used as anchor features and a plurality of second contour lines 387 is directly obtained from the center points 321 as anchor features. The center points can for example be generated by template matching techniques or involving a correlation technique.

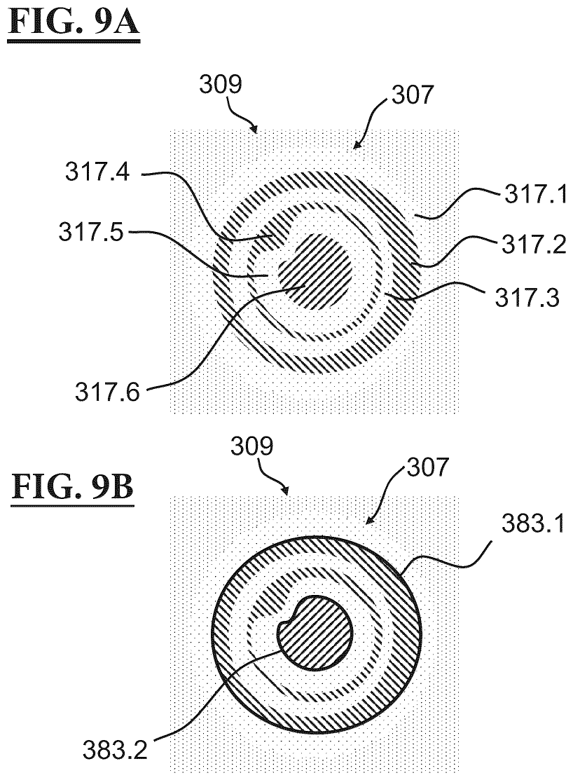

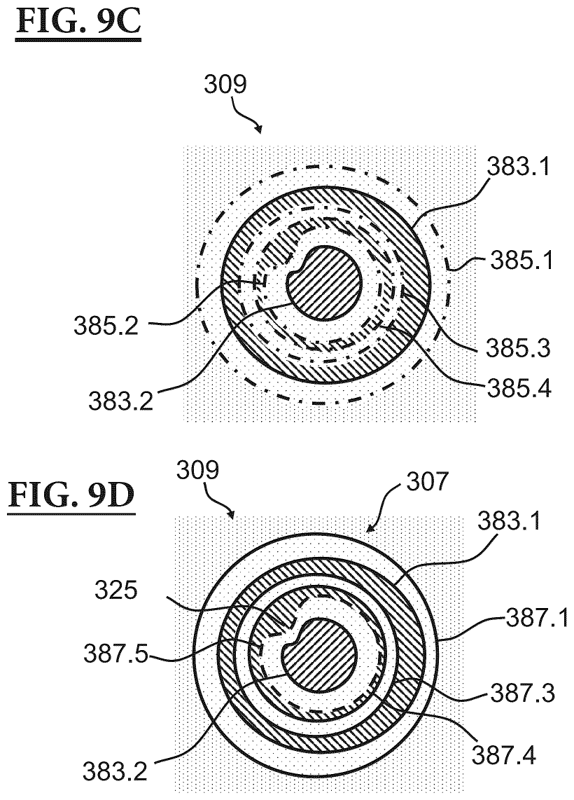

FIGS. 9A-D illustrate another example of the method according to the first embodiment. In FIG. 9A, a cross section image segment 309 of a HAR channel 307 comprising six ring zones 317.1 to 317.6 is shown. Two anchor features are selected on step SO, the central ring zone 317.6 and the second ring zone 317.2. In step S2, the contours lines 383.1 and 383.2 of the two anchor features are determined. In step S3.1, the contours 383.1 and 383.2 are scaled to match the contours of the second features. For the outer ring zones 317.1 to 317.4, the first contour line 383.1 is scaled to achieve contour proposals 385.1, 385.3 and 385.4. The contour line 383.2 of the second anchor feature 317.6 is scaled to obtain contour proposal of the next neighboring contour 385.2 of ring zone 317.5. In step 3.2, the final contours 387.1 to 387.5 of the ring zones 317.1, 317.3 to 317.5 are determined. As an example, in internal deformation 325 of ring zones is hereby determined.

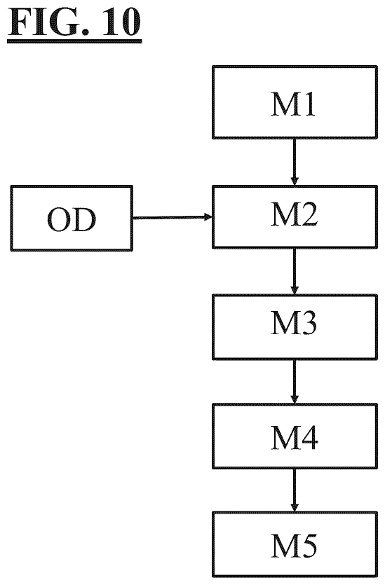

FIG. 10 illustrates an application an object detector OD achieved by a method according to the first embodiment. In step M1, a new cross-section image slice is received. In step M2, a plurality of instances of semiconductor objects of interest are detected in the new cross-section image slice by the object detector OD, and a segmentation of each instance of a semiconductor object of interest is performed by object detector. In step M3, a measurement is performed for each instance of the semiconductor object of interest and a measurement result is stored in a memory. In step M4, a plurality of measurement results from a plurality of cross-section image slice is analyzed, and for example a statistical analysis of properties of semiconductor object of interest during a semiconductor manufacturing process is performed. In step M5, the result of the analysis is used to modify a semiconductor manufacturing process.

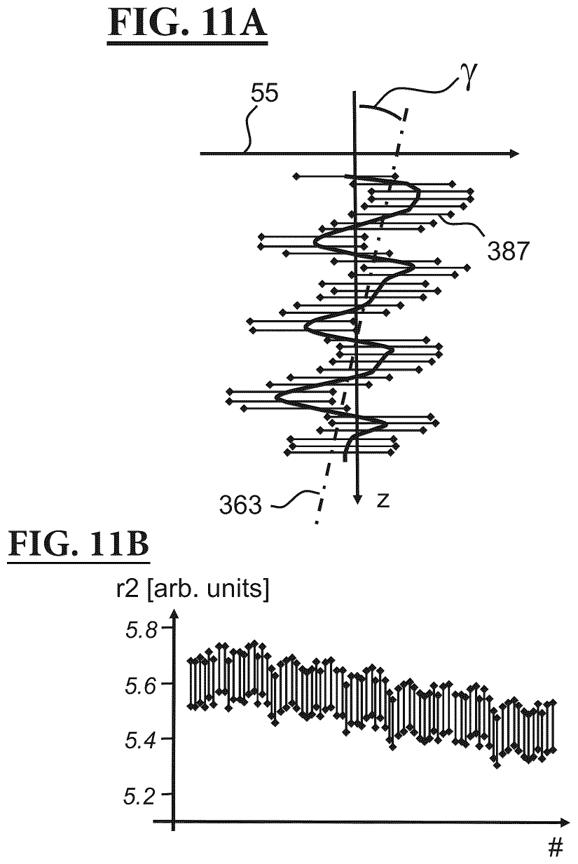

FIGS. 11A-11B show a result of step MA. In FIG. 11A, a trajectory of center coordinates of an HAR channel is shown. Each horizontal line corresponds to one contour of a second feature 387, measured at a depth z inside an inspection volume of a wafer. Thereby, a HAR channel can be analyzed and for example an average tilt angle g of average channel trajectory 363 is determined. FIG. 11B illustrates a distribution of measured radius r2 of a plurality of wafer samples. The radius r2 shows a significant drift over wafer samples, which can be an indicator for a process drift during the manufacturing process of wafer.

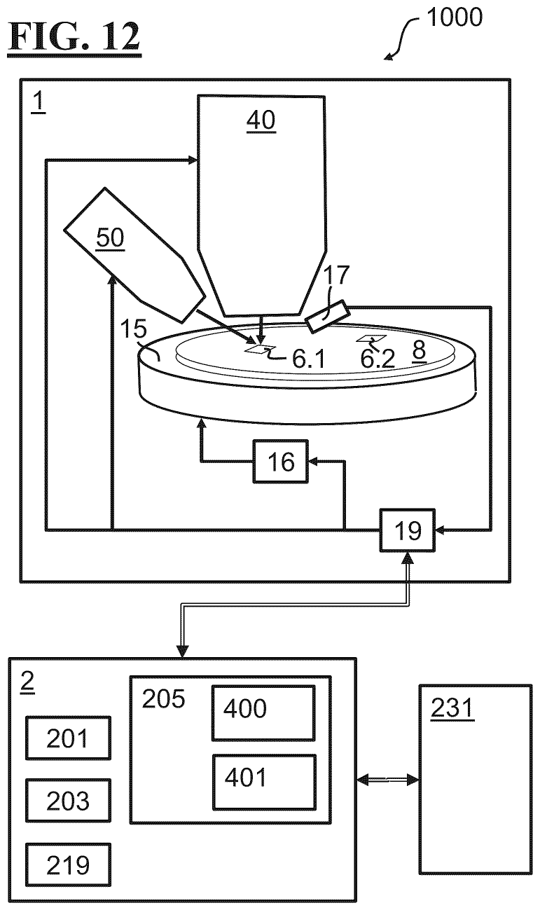

A wafer inspection system configured for executing the method according to the first embodiment is described in the second embodiment. An example of such a wafer inspection system is shown in FIG. 12. The wafer inspection system 1000 comprises a dual beam system 1. A dual beam system is illustrated in FIG. 1 with more detail and reference is made to the description of FIG. 1. Features of a dual beam system 1 include a first charged particle or FIB column 50 for milling and a second, charged particle beam imaging system 40 for high-resolution imaging of cross section surfaces. A dual beam system 1 comprises at least one detector 17 for detecting secondary particles, which can be electrons or photons. A dual beam system 1 further comprises a wafer support table 15 configured for holding during use a wafer 8. The wafer support table 15 is position controlled by a stage control unit 16, which is connected to the control unit 19 of the dual beam system 1. The control unit 19 is configured with memory and logic to control operation of the dual beam system 1.

The wafer inspection system 1000 further comprises an operation control unit 2. The operation control unit 2 comprises at least one processing engine 201, which can be formed by multiple parallel processors including GPU processors and a common, unified memory. The operation control unit 2 further comprises an SSD memory and disk memory or storage 203 for storing training data, a trained machine learning algorithm, and a plurality of cross section images. The operation control unit 2 further comprises a user interface 205, comprising the user interface display 400 and user command devices 401, configured for receiving input from a user. The operation control unit 2 further comprises a memory or storage 219 for storing process information of the image generation process of the dual beam device 1 and for storing software instructions, which can be executed by the processing engine 201. The process information of the image generation process with the dual beam device 1 can for example include a library of the effects during the image generation and a list of predetermined material contrasts. The software instructions comprise software for performing a method according to the first embodiment.

The operation control unit 2 is further connected to an interface unit 231, which is configured to receive further commands or data, for example CAD data, from external devices or a network. The interface unit 231 is further configured to exchange information, for example receive instructions from external devices or provide measurement results to external devices or store a set of training data or a trained machine learning algorithm or plurality of cross section images in external storages.

The processing engine 201 is configured to consider process information of the image generation process with for example a dual beam device 1, including for example selected imaging parameters of the dual beam system. The imaging parameters can for example be selected by a user according to a desired speed or accuracy of the measurement task.

The inspection system 1000 is configured to receive user information as specified in step SO of the method according to the first embodiment, for example comprising CAD information of the semiconductor object of interest and the selection of an anchor feature. The inspection system 1000 can be configured to combine the user information with process information of the image generation process. The processing engine 201 is further configured to execute the method steps S1 to S5 of the method described above. The processing engine 201 is thereby configured to display information via the user display 400 and to receive user input via user interface 401. The processing engine 201 is further configured to train the object detector OD with the training data generated during iterative operation of Step S1 to S4. With the second embodiment, an inspection system 1000, configured for segmenting and annotating images with high throughput is provided.

The foregoing examples are described for the segmentation and annotation of HAR channels. The methods can of course also be applied to other semiconductor objects of interest. The methods can further be applied for example to a raster of repetitive semiconductor objects of interest.

The method and inspection system can be used for quantitative metrology, but can also be used for defect detection, process monitoring, defect review, and inspection of integrated circuits within semiconductor wafers. With the image segmentation and annotation method according to the first embodiment, the first step of a wafer inspection task utilizing machine learning algorithms is improved. The disclosure provides for example a method and a device for generating training data with reduced user interaction. The method and a inspection device for generating training data relies on prior knowledge of the objects to be measured, including a selection of an anchor feature and the determination of a transfer property. Prior knowledge is for example given by CAD information.

The disclosure can be described by following clauses:
Clause 1: A method of contour extraction of a semiconductor object of interest, comprising:
   selecting a first feature of the semiconductor object of interest (307) as an anchor feature (317.1);
   defining a transfer property from a first contour (381, 383) of the anchor feature (317.1) to a second contour (385) of a second feature (317.2) of the semiconductor object of interest (307);
   obtaining at least one cross-section image (309, 311) comprising at least one cross-section of the semiconductor object of interest (307);
   generating a first contour (381, 383) of the anchor feature (317.1) in the cross-section image (309, 311);
   determining a second contour (385, 387) from the first contour (381,383) with the transfer property.
Clause 2: The method according to clause 1, wherein generating the first contour (381, 383) comprises generating an initial contour proposal (381) from a cross-section image (309, 311) by image processing comprising at least one member of the group consisting of an intensity calibration, threshold operation, a computation of an intensity gradient, or a computation of the NILS.
Clause 3: The method of clause 2, wherein generating the first contour (383) comprises modifying the initial contour proposal (381) by image processing comprising at least one member of the group consisting of a smoothing, an interpolation, a contour closing, a contour vector extraction, or an active contour model.
Clause 4: The method of clause 3, wherein the image processing is based on prior knowledge of the contour shape of the anchor feature (317.1).
Clause 5: The method according to any of the clauses 1 to 4, wherein the transfer property for determining the second contour (385, 387) comprises at least on member of a group consisting of a scaling, an anisotropic scaling, a morphing operation, a shift, a rotation, a shearing, or a template scaling.
Clause 6: The method according to any of the clauses 1 to 5, wherein determining a second contour (387) further comprises an image processing comprising at least one member of the group consisting of a smoothing, an interpolation, a contour closing, a contour vector extraction, or an active contour model.
Clause 7: The method according to any of the clauses 1 to 6, further comprising a detection of at least on instance of a semiconductor object of interest (307) within a cross-section image (309, 311) by a method comprising a member of the group consisting of a template matching, a thresholding, or a correlation technique.
Clause 8: The method according to any of the clauses 1 to 7, further comprising at least one member of a group consisting of a registration, a distortion correction, a magnification adjustment, a computation of a depth map, a contrast enhancement, and a noise filtering of a cross-section image (309, 311).
Clause 9: The method according to any of the clauses 1 to 8, comprising iteratively repeating the obtaining of cross-section images (309, 311), generating first contours (381, 383) and determining a second contours (385, 387) with the transfer property.
Clause 10: The method according to any of the clauses 1 to 8, further comprising an annotation of at least one cross-section image (309, 311) with pixel values according to the first and second contours (381, 383, 385, 387).
Clause 11: The method according to clause 10, further comprising training an object detector OD with at least one annotated cross-section image (309, 311).
Clause 12: The method according to any of the clauses 1 to 9, comprising determining a property of a second feature (317.2), the property comprising at least a member of the group consisting of a diameter, an area, a center of gravity, a deviation of a shape, an eccentricity, a distance.
Clause 13: A wafer inspection system (1000) comprising a dual beam system (1) and an operation control unit (2), comprising at least one processing engine (201) and a memory (219), the processing engine (201) being configured to execute software instructions stored in the memory (219) comprising instructions according to a method of any of the clauses 1 to 12.
Clause 14: The wafer inspection system (1000), further comprising an interface unit 231 and a user interface 205 configured to receive, display, send, or store information.
Clause 15: The wafer inspection system (1000) according to clause 13 or 14, wherein the dual beam system (1) comprises a focused ion beam (FIB) system and a charged particle beam imaging system arranged at an angle such that during use, a focused ion beam and a charged particle beam form an intersection point, configured such that during use at least a cross section image (309, 311) is formed through an inspection volume of a wafer at a slanted angle GF with respect to a wafer surface (55).

The disclosure described by examples and embodiments is however not limited to the clauses but can be implemented by those skilled in the art by various combinations or modifications.

A list of reference numbers is provided:
1 Dual Beam system
2 Operation Control Unit
4 first cross section image features
6 measurement sites
8 wafer
15 wafer support table
16 stage control unit
17 Secondary Electron detector
19 Control Unit
40 charged particle beam (CPB) imaging system
42 Optical Axis of imaging system
43 Intersection point
44 Imaging charged particle beam
48 FIB Optical Axis
50 FIB column
51 focused ion beam
52 cross-section surface
53 cross-section surface
55 wafer top surface
155 wafer stage
160 inspection volume
201 processing engine
203 memory
205 User interface
219 memory
1231 Interface unit
307 measured cross section image of HAR structure
309 image segment
311 cross section image slice
313 word lines
315 edge with surface
317 semiconductor object of interest, here ring zones of HAR structure
318 noise
320 partially merged outer contour
321 center position
325 defect or deviation
327 pixelwise annotated rings
363 average HAR channel trajectory
379 contour gap
381 initial contour proposal
383 contour line of first feature
385 second contour proposal
387 contour of second feature
391 transfer property, here scaling vector
400 user interface display
401 user command devices
1000 Wafer inspection system

What is claimed is:

1. A method, method comprising:
a) selecting a first feature of a semiconductor object as an anchor feature;
b) defining a transfer property from a first contour of the anchor feature to a second contour of a second feature of the semiconductor;
c) obtaining a cross-section image comprising a cross-section of the semiconductor;
d) generating the first contour of the anchor feature in the cross-section image; and
e) determining a second contour from the first contour using the transfer property.

2. The method according to claim 1, wherein d) comprises generating an initial contour proposal from the cross-section image by image processing comprising at least one member selected from the group consisting of an intensity calibration, a threshold operation, a computation of an intensity gradient, and a computation of a normalized image log slope.

3. The method of claim 2, wherein d) comprises modifying the initial contour proposal by image processing comprising at least one member selected from the group consisting of a smoothing, an interpolation, a contour closing, a contour vector extraction, and an active contour model.

4. The method of claim 3, wherein the image processing is based on prior knowledge of the contour shape of the anchor feature.

5. The method of claim 2, wherein e) comprises at least one member selected from the group consisting of a scaling, an anisotropic scaling, a morphing operation, a shift, a rotation, a shearing, and a template scaling.

6. The method of claim 2, wherein e) comprises an image processing comprising at least one member selected from the group consisting of a smoothing, an interpolation, a contour closing, a contour vector extraction, and an active contour model.

7. The method of claim 1, wherein e) comprises at least one member selected from the group consisting of a scaling, an anisotropic scaling, a morphing operation, a shift, a rotation, a shearing, and a template scaling.

8. The method of claim 1, wherein e) comprises an image processing comprising at least one member selected from the group consisting of a smoothing, an interpolation, a contour closing, a contour vector extraction, and an active contour model.

9. The method of claim 1, further comprising detecting an instance of the semiconductor object within the cross-section image by a method comprising a member selected from the group consisting of a template matching, a thresholding, and a correlation technique.

10. The method of claim 1, further comprising at least one member selected from the group consisting of a registration, a distortion correction, a magnification adjustment, a computation of a depth map, a contrast enhancement, and a noise filtering of a cross-section image.

11. The method of claim 1, further comprising iteratively repeating b), c) and d).

12. The method of claim 1, further comprising annotating a cross-section image with pixel values according to the first and second contours.

13. The method of claim 12, further comprising training an object detector with the annotated cross-section image.

14. The method of claim 1, comprising determining a property of a second feature, wherein the property comprises at least a member of the group consisting of a diameter, an area, a center of gravity, a deviation of a shape, an eccentricity, and a distance.

15. One or more machine-readable hardware storage devices comprising instructions that re executable by one or more processing device to perform operations comprising the method of claim 1.

16. A system, comprising:
one or more processing devices; and
one or more machine-readable hardware storage devices comprising instructions that re executable by one or more processing device to perform operations comprising the method of claim 1.

17. The system of claim 16, further comprising a dual beam system.

18. The system of claim 17, further comprising:
an interface unit; and
a user interface configured to receive, display, send, or store information.

19. The system of claim 17, wherein:
the dual beam system comprises:
a focused ion beam system configured to generate a focused ion beam; and
a charged particle beam imaging system configured to generate a charged particle beam;
the focused ion beam system and charged particle beam imaging system are disposed at an angle so that during use, the focused ion beam and the charged particle beam define an intersection point.

20. The system of claim 17, wherein the system is a wafer inspection system.
